(19) United States
(12) Patent Application Publication
(10) Pub. No.: US 2019/0252215 A1
(43) Pub. Date: Aug. 15, 2019

(54) APPARATUS AND METHOD FOR CLEANING SEMICONDUCTOR WAFERS

(71) Applicant: ACM Research (Shanghai) Inc., Shanghai (CN)

(72) Inventors: Hui Wang, Shanghai (CN); Xi Wang, Shanghai (CN); Zhenming Chu, Shanghai (CN); Fuping Chen, Shanghai (CN)

(73) Assignee: ACM Research (Shanghai) Inc., Shanghai (CN)

(21) Appl. No.: 16/344,252

(22) PCT Filed: Oct. 25, 2016
(86) PCT No.: PCT/CN2016/103151

§ 371 Date: Apr. 23, 2019

(51) Int. Cl. H01L 21/67; H01L 21/02; B08B 3/12; B08B 3/02

(52) U.S. Cl. CPC H01L 21/67051; B08B 3/022; B08B 3/123; H01L 21/02057

(57) ABSTRACT

An apparatus for cleaning a semiconductor wafer comprises a chuck (106), an ultra or mega sonic device, an actuator (113), at least one dispenser (108, 209) and a rotating driving mechanism (111). The chuck (106) holds the semiconductor wafer (105). The actuator (113) drives the ultra or mage sonic device to a position above the surface of the semiconductor wafer (105) and a gap is formed between the ultra or mega sonic device and the surface of the semiconductor wafer (105). The at least one dispenser (108, 209) sprays cleaning liquid on the surface of the semiconductor wafer (105). The rotating driving mechanism drives the chuck (106) to rotate at a spin speed lower than a set spin speed for ensuring that the gap between the ultra or mega sonic device and the surface of the semiconductor wafer (105) is fully and continuously filled with the cleaning liquid (104), making the ultra or mega sonic energy be stably transferred to the entire surface of the semiconductor wafer (105) through the cleaning liquid (104). A method for cleaning a semiconductor wafer is also disclosed.

### FIELD OF THE INVENTION

The present invention generally relates to an apparatus and a method for cleaning a semiconductor wafer. More particularly, relates to using an ultra or mega sonic device to clean a semiconductor wafer and controlling the spin speed of the semiconductor wafer lower than a set spin speed for making cleaning liquid fully and continuously fill a gap between the ultra or mega sonic device and the semiconductor wafer, so that the ultra or mega sonic energy is stably transferred to the semiconductor wafer through the cleaning liquid, avoiding damaging patterned structures on the semiconductor wafer.

### BACKGROUND

As the volume of a semiconductor chip becomes smaller, a big challenge in today's semiconductor cleaning technology is to avoid damaging patterned structures on a semiconductor wafer and improve particles removal rate. An ultra or mega sonic cleaning technology development solves cleaning problems during the fabrication of semiconductor devices, which is more applied in single semiconductor wafer cleaning and can efficiently remove particles and contaminants. Taking a mega sonic device for example, a mega sonic device generally includes a piezoelectric transducer acoustically coupled to a resonator. The transducer is electrically excited such that it vibrates and the resonator transmits high frequency sound energy into cleaning liquid. The agitation of the cleaning liquid produced by the mega sonic energy loosens particles on the semiconductor wafer. Contaminants are thus vibrated away from the semiconductor wafer, and removed from the surface of the semiconductor wafer through the flowing cleaning liquid supplied by a dispenser. When cleaning the semiconductor wafer, the semiconductor wafer is supported by a chuck and the semiconductor wafer rotates along with the chuck at a spin speed. The dispenser sprays the cleaning liquid on the surface of the semiconductor wafer. The mega sonic device is driven to a position above the surface of the semiconductor wafer and a gap is formed between the mega sonic device and the surface of the semiconductor wafer. The cleaning liquid fills the gap between the mega sonic device and the surface of the semiconductor wafer. The mega sonic energy is transferred to the surface of the semiconductor wafer through the cleaning liquid. During the semiconductor device fabrication process, the cleaning liquid between the mega sonic device and the semiconductor wafer can obviously affect patterned structures quality. The spin speed of the semiconductor wafer is a main factor to affect the cleaning liquid filling the gap between the mega sonic device and the surface of the semiconductor wafer. If the cleaning liquid does not fully fill the gap between the mega sonic device and the surface of the semiconductor wafer, the patterned structures on the semiconductor wafer may be damaged because the mega sonic energy is unstably transferred to the surface of the semiconductor wafer. Besides the spin speed of the semiconductor wafer, the position of the mega sonic device above the surface of the semiconductor wafer, and the semiconductor wafer surface characteristic (hydrophobic or hydrophilic), etc. also can affect the cleaning liquid filling the gap between the mega sonic device and the surface of the semiconductor wafer, which may lead to the cleaning liquid not fully and continuously fill the whole gap between the mega sonic device and the surface of the semiconductor wafer, causing the patterned structures damage.

### SUMMARY

Accordingly, an object of the present invention is to provide an apparatus and a method for cleaning a semiconductor wafer, using an ultra or mega sonic device and controlling the spin speed of the semiconductor wafer lower than a set spin speed for making cleaning liquid fully and continuously fill a gap between the ultra or mega sonic device and the surface of the semiconductor wafer, so that the ultra or mega sonic energy is stably transferred to the entire surface of the semiconductor wafer through the cleaning liquid, avoiding the ultra or mega sonic energy damaging patterned structures on the semiconductor wafer.

In one embodiment of the present invention, an apparatus for cleaning a semiconductor wafer includes a chuck, a rotating driving mechanism, an ultra or mega sonic device, an actuator, and at least one center dispenser. The chuck holds the semiconductor wafer. The rotating driving mechanism drives the chuck to rotate at a spin speed lower than 30 rpm. The actuator drives the ultra or mega sonic device to a position above the surface of the semiconductor wafer and a gap is formed between the ultra or mega sonic device and the surface of the semiconductor wafer. The at least one center dispenser sprays cleaning liquid on the surface of the semiconductor wafer. The gap between the ultra or mega sonic device and the surface of the semiconductor wafer is fully and continuously filled with the cleaning liquid, so that the ultra or mega sonic energy is stably transferred to the entire surface of the semiconductor wafer through the cleaning liquid.

In another embodiment of the present invention, an apparatus for cleaning a semiconductor wafer includes a chuck, a rotating driving mechanism, an ultra or mega sonic device, an actuator, and a side dispenser. The chuck holds the semiconductor wafer. The rotating driving mechanism drives the chuck to rotate at a spin speed lower than 45 rpm. The actuator drives the ultra or mega sonic device to a position above the surface of the semiconductor wafer and a gap is formed between the ultra or mega sonic device and the surface of the semiconductor wafer. The side dispenser sprays cleaning liquid on the surface of the semiconductor wafer. The gap between the ultra or mega sonic device and the surface of the semiconductor wafer is fully and continuously filled with the cleaning liquid, so that the ultra or mega sonic energy is stably transferred to the entire surface of the semiconductor wafer through the cleaning liquid.

In one embodiment of the present invention, a method for cleaning a semiconductor wafer includes the following steps: holding a semiconductor wafer by a chuck; spraying cleaning liquid on the surface of the semiconductor wafer by at least one center dispenser; driving an ultra or mage sonic device to a position above the surface of the semiconductor wafer and a gap formed between the ultra or mega sonic device and the surface of the semiconductor wafer; and driving the chuck to rotate at a spin speed lower than 30 rpm for ensuring that the gap between the ultra or mega sonic device and the surface of the semiconductor wafer is fully and continuously filled with the cleaning liquid, making the ultra or mega sonic energy be stably transferred to the entire surface of the semiconductor wafer through the cleaning liquid.

In another embodiment of the present invention, a method for cleaning a semiconductor wafer includes the following steps: holding a semiconductor wafer by a chuck; spraying cleaning liquid on the surface of the semiconductor wafer by at least one side dispenser; driving an ultra or mage sonic device to a position above the surface of the semiconductor wafer and a gap formed between the ultra or mega sonic device and the surface of the semiconductor wafer; and driving the chuck to rotate at a spin speed lower than 45 rpm for ensuring that the gap between the ultra or mega sonic device and the surface of the semiconductor wafer is fully and continuously filled with the cleaning liquid, making the ultra or mega sonic energy be stably transferred to the entire surface of the semiconductor wafer through the cleaning liquid.

### BRIEF DESCRIPTION OF THE DRAWINGS

FIG. 1A is a schematic view showing an apparatus for cleaning a semiconductor wafer according to a first embodiment of the present invention, and

FIG. 1B is a top view showing using an ultra or mega sonic device and a center dispenser of the apparatus to clean the semiconductor wafer.

FIG. 2 is a top view showing using an ultra or mega sonic device and a side dispenser of an apparatus according to a second embodiment of the present invention to clean a semiconductor wafer.

FIG. 3A and FIG. 3B are top views showing how cleaning liquid coverage area changes during the semiconductor wafer rotating at a high spin speed (>30 rpm) and a center dispenser spraying cleaning liquid on the surface of the semiconductor wafer to fill a gap between the semiconductor wafer and an ultra or mega sonic device, and FIG. 3C and FIG. 3D are schematic views showing how cleaning liquid coverage area changes during the semiconductor wafer rotating at a high spin speed.

FIG. 4 is a schematic view showing using the apparatus shown in FIGS. 1A and 1B to clean a semiconductor wafer, wherein the semiconductor wafer is rotating at a low spin speed (10-30 rpm) and the center dispenser is spraying cleaning liquid on the surface of the semiconductor wafer to fill the gap between the semiconductor wafer and the ultra or mega sonic device.

FIG. 5 is a schematic view showing using the apparatus shown in FIG. 2 to clean a semiconductor wafer, wherein the semiconductor wafer is rotating at a low spin speed (10-45 rpm) and the side dispenser is spraying cleaning liquid on the surface of the semiconductor wafer to fill a gap between the semiconductor wafer and the ultra or mega sonic device.

FIG. 6 is a schematic view showing using the apparatus shown in FIG. 2 to clean a semiconductor wafer, wherein the semiconductor wafer is rotating at a high spin speed (>45 rpm) and the side dispenser is spraying cleaning liquid on the surface of the semiconductor wafer to fill the gap between the semiconductor wafer and the ultra or mega sonic device.

FIG. 7 is a schematic view showing using the apparatus shown in FIGS. 1A and 1B to clean a semiconductor wafer, wherein the surface of the semiconductor wafer is hydrophobic, and the semiconductor wafer is rotating at a low spin speed (10-30 rpm) and the center dispenser is spraying cleaning liquid on the surface of the semiconductor wafer to fill the gap between the semiconductor wafer and the ultra or mega sonic device.

FIG. 8 is a schematic view showing using the apparatus shown in FIGS. 1A and 1B to clean a semiconductor wafer, wherein the surface of the semiconductor wafer is hydrophilic, and the semiconductor wafer is rotating at a low spin speed (10-30 rpm) and the center dispenser is spraying cleaning liquid on the surface of the semiconductor wafer to fill the gap between the semiconductor wafer and the ultra or mega sonic device.

### DETAILED DESCRIPTION

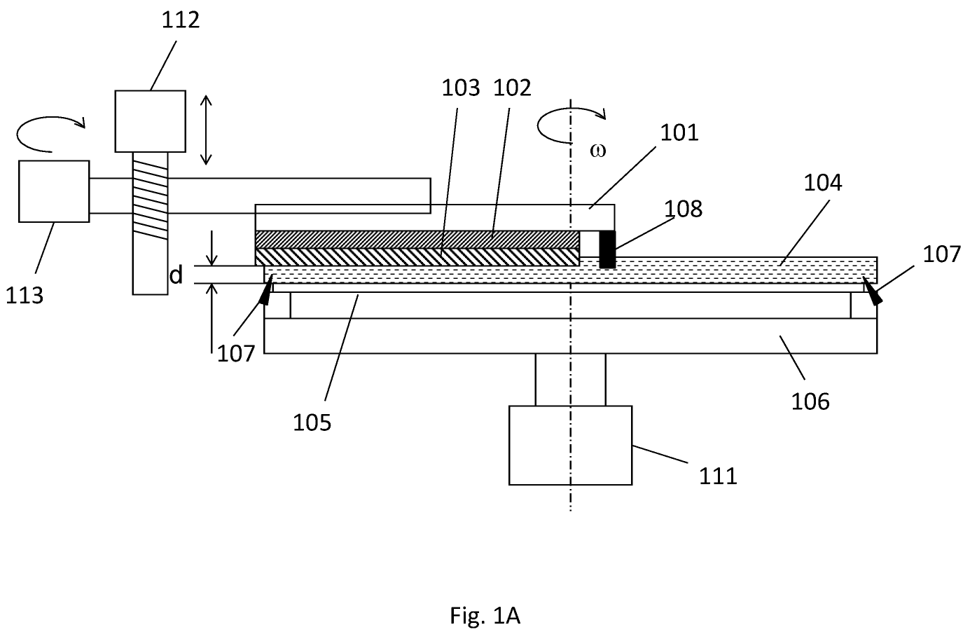

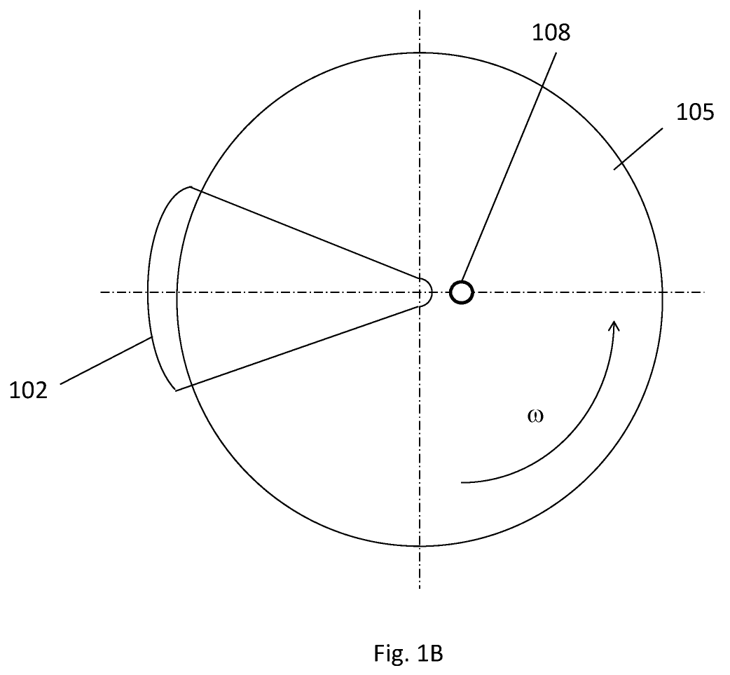

Referring to FIG. 1A and FIG. 1B, an exemplary apparatus for cleaning a semiconductor wafer according to a first embodiment of the present invention is illustrated. The apparatus includes a chuck 106 for holding a semiconductor wafer 105. A plurality of locating pins 107 is disposed on the chuck 106 for fixing the semiconductor wafer 105. The chuck 106 connects to a rotating driving mechanism 111. The rotating driving mechanism 111 drives the chuck 106 to rotate at a spin speed lower than a set spin speed. The spin speed is set in range of 10-3000 rpm. As the semiconductor wafer 105 is held by the chuck 106, the semiconductor wafer 105 rotates along with the chuck 106 at the same spin speed. The apparatus has a suspension arm 101. An ultra or mega sonic device is positioned at the bottom of the suspension arm 101. The ultra or mega sonic device has a piezoelectric transducer 102 acoustically coupled to a resonator 103. When using the ultra or mega sonic device to clean the semiconductor wafer 105, the ultra or mega sonic device is moved to a position above the surface of the semiconductor wafer 105 and a gap is formed between the ultra or mega sonic device and the surface of the semiconductor wafer 105. The piezoelectric transducer 102 is electrically excited such that it vibrates and the resonator 103 transmits high frequency sound energy into cleaning liquid. The agitation of the cleaning liquid produced by the ultra or mega sonic energy loosens particles on the semiconductor wafer 105. Contaminants are thus vibrated away from the surface of the semiconductor wafer 105, and removed from the surface of the semiconductor wafer 105 through the flowing cleaning liquid 104. The cleaning liquid 104 is supplied by at least one center dispenser 108. The center dispenser 108 is positioned at the tip end of the suspension arm 101. The center dispenser 108 is opposite the center of the semiconductor wafer 105 or slightly over the center of the semiconductor wafer 105 for spraying cleaning liquid 104 on the surface of the semiconductor wafer 105. The cleaning liquid 104 fully and continuously fills the gap between the ultra or mega sonic device and the surface of the semiconductor wafer 105, making the ultra or mega sonic energy be stably transferred to the entire surface of the semiconductor wafer 105 through the cleaning liquid 104, avoiding the ultra or mega sonic energy damaging patterned structures on the semiconductor wafer 105, especially avoiding the ultra or mega sonic energy damaging the patterned structures on the edge of the semiconductor wafer 105. The number of the center dispenser 108 is at least one or more than one. The center dispenser 108 can dispense different chemicals which can be liquid or gas on the surface of the semiconductor wafer 105. A vertical actuator 112 drives the suspension arm 101 to move up or down to change the gap between the ultra or mega sonic device and the surface of the semiconductor wafer 105. An actuator 113 drives the ultra or mega sonic device to a position above the surface of the semiconductor wafer 105.

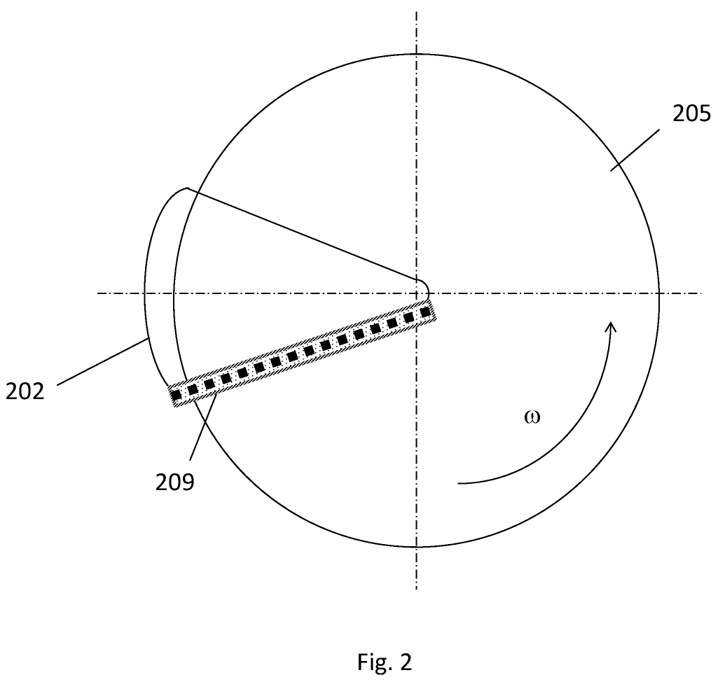

Referring to FIG. 2, FIG. 2 is a top view showing an exemplary apparatus for cleaning a semiconductor wafer according to a second embodiment of the present invention. The apparatus of the second embodiment is similar to the apparatus shown in FIG. 1, and the difference is that the apparatus of the second embodiment has a side dispenser 209 which is disposed at a side of an ultra or mega sonic device of the apparatus. In an embodiment, the side dispenser 209 has a plurality of jetting holes which are arranged in a line disposed along the side of the ultra or mega sonic device.

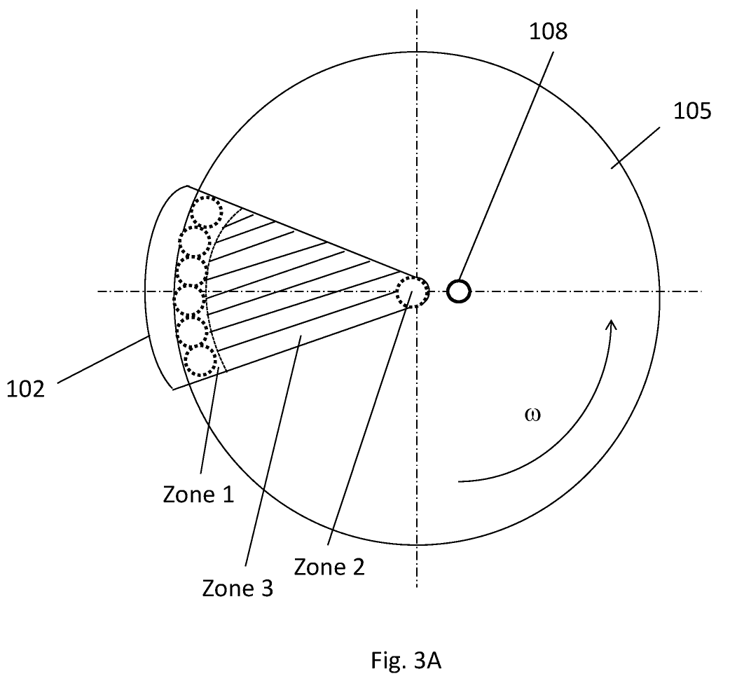

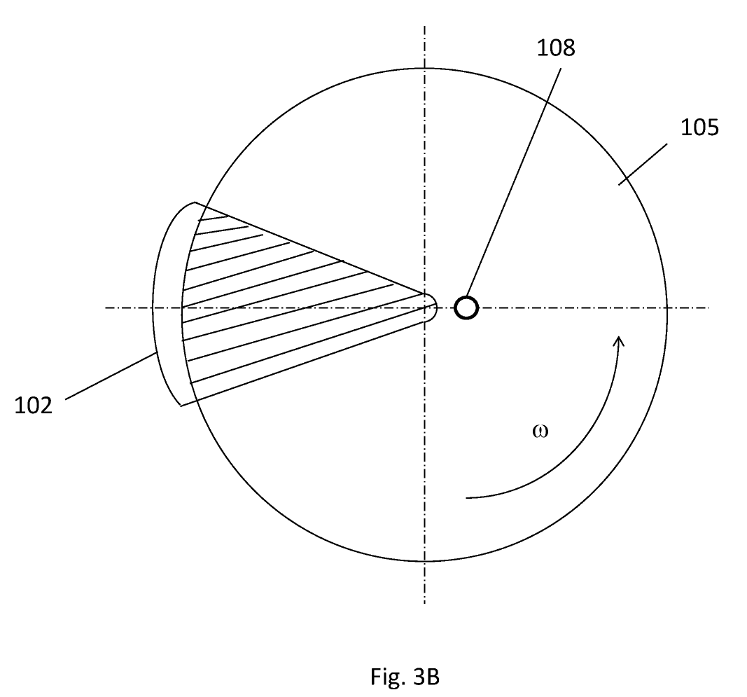

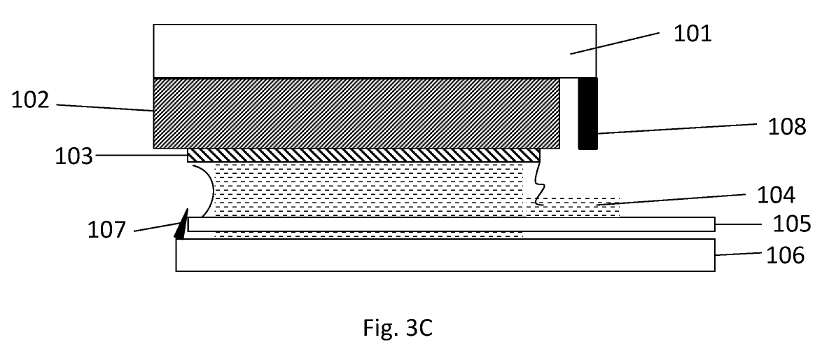

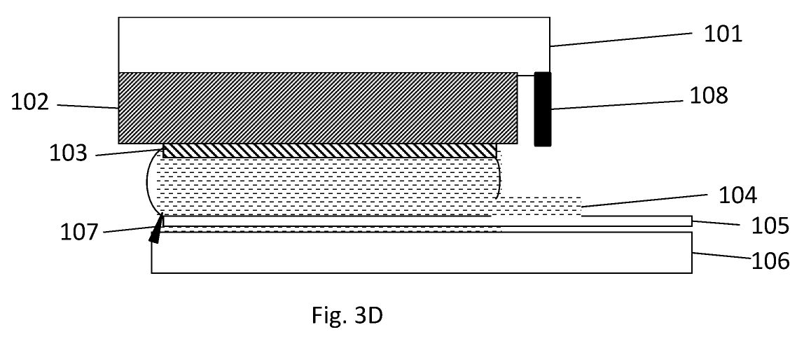

In one embodiment as shown in FIGS. 3A to 3D, when using the apparatus shown in FIG. 1A and FIG. 1B to clean the semiconductor wafer 105, the chuck 106 holds and positions the semiconductor wafer 105 by the plurality of locating pins 107. The rotating driving mechanism 111 drives the chuck 106 to rotate at a high spin speed which is larger than 30 rpm. The actuator 113 drives the ultra or mega sonic device to a position above the surface of the semiconductor wafer 105. The vertical actuator 112 drives the ultra or mega sonic device to move vertically for changing the gap between the ultra or mega sonic device and the surface of the semiconductor wafer 105. The ultra or mega sonic device covers the outer edge of the semiconductor wafer 105. The center dispenser 108 sprays cleaning liquid 104 on the surface of the semiconductor wafer 105. The rotating driving mechanism 111 drives the chuck 106 to rotate at a high spin speed, which causes the gap between the ultra or mega sonic device and the surface of the semiconductor wafer 105 cannot be fully and continuously filled with the cleaning liquid 104, especially at the edge of the ultra or mega sonic device. During the cleaning process, the cleaning liquid 104 fully fills the gap between the ultra or mega sonic device and the surface of the semiconductor wafer 105 off and on, which is unsteady. FIG. 3A and FIG. 3B are top views showing how cleaning liquid coverage area changes during the semiconductor wafer rotating at a high spin speed. Zone 1 and zone 2 are fully filled with the cleaning liquid 104 off and on. Sometimes, zone 1 and zone 2 are not or non-fully filled with the cleaning liquid 104, and zone 3 is fully filled with the cleaning liquid 104, as shown in FIG. 3A and FIG. 3C. But sometimes, zone 1 and zone 2 are fully filled with the cleaning liquid 104, as shown in FIG. 3B and FIG. 3D, so that the entire gap between the ultra or mega sonic device and the surface of the semiconductor wafer 105 is fully filled with the cleaning liquid 104. The gas and liquid phases alternating exists in the gap between the ultra or mega sonic device and the surface of the semiconductor wafer 105. The ultra or mega sonic energy concentrates between the interface of gas and liquid phases. The high ultra or mega sonic power generated by the energy concentration has the risk of the patterned structures damage. Besides, when there is no cleaning liquid 104 filling the zone 1 and zone 2 or the zone 1 and zone 2 is not fully filled with the cleaning liquid 104, where the ultra or mega sonic energy is not transferred to the surface of the semiconductor wafer 105, but once the zone 1 and zone 2 is fully filled with the cleaning liquid 104, the ultra or mega sonic energy is transferred to the surface of the semiconductor wafer 105 through the cleaning liquid 104. It results in a non-uniform distribution of the ultra or mega sonic energy transferred to the surface of the semiconductor wafer 105. Besides, the unstable liquid transferring also causes the turbulence flow, where the ultra or mega sonic energy transferring is further not uniform.

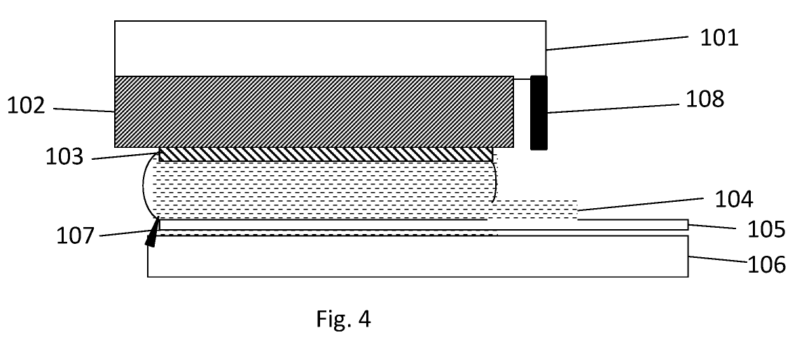

Referring to FIG. 4, for solving the above problems, the spin speed of the chuck 106 is controlled at a low spin speed which is smaller than 30 rpm, preferably in the range of 10-30 rpm. The center dispenser 108 sprays cleaning liquid 104 on the surface of the semiconductor wafer 105. Because the rotating driving mechanism 111 drives the chuck 106 to rotate at a spin speed lower than a set spin speed, making the gap between the ultra or mega sonic device and the surface of the semiconductor wafer 105 be fully and continuously filled with the cleaning liquid 104, therefore, the ultra or mega sonic energy is stably transferred to the entire surface of the semiconductor wafer 105 through the cleaning liquid 104, avoiding damaging the patterned structures on the semiconductor wafer 105. Controlling the spin speed of the chuck 106 at a spin speed lower than a set spin speed can avoid the patterned structures damage.

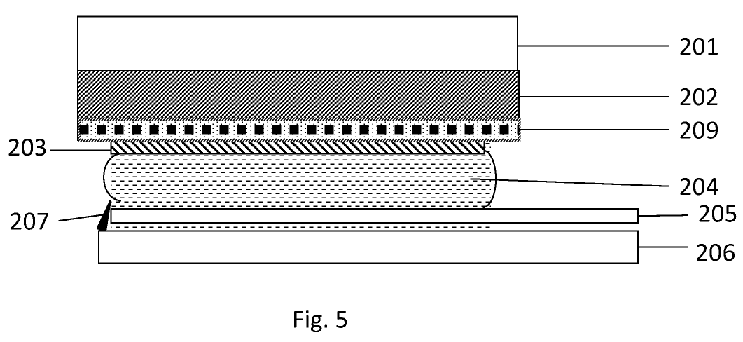

Referring to FIG. 5, when using the apparatus shown in FIG. 2 to clean the semiconductor wafer 205, the chuck 206 holds and positions the semiconductor wafer 205 by the plurality of locating pins 207. The rotating driving mechanism drives the chuck 206 to rotate at a low spin speed which is smaller than 45 rpm, preferably in the range of 10-45 rpm. The actuator drives the ultra or mega sonic device to a position above the surface of the semiconductor wafer 205. The vertical actuator drives the suspension arm 201 to move vertically for changing the gap between the ultra or mega sonic device and the surface of the semiconductor wafer 205. Preferably, the edge of the ultra or mega sonic device is aligned with the outer edge of the semiconductor wafer 205. The side dispenser 209 sprays cleaning liquid 204 on the surface of the semiconductor wafer 205. Because the rotating driving mechanism drives the chuck 206 to rotate at a spin speed lower than a set spin speed, making the gap between the ultra or mega sonic device and the surface of the semiconductor wafer 205 be fully and continuously filled with the cleaning liquid 204, therefore, the ultra or mega sonic energy is stably transferred to the entire surface of the semiconductor wafer 205 through the cleaning liquid 204, avoiding the ultra or mega sonic energy damaging the patterned structures on the semiconductor wafer 205. Controlling the spin speed of the chuck 206 at a spin speed lower than a set spin speed can avoid the patterned structures damage.

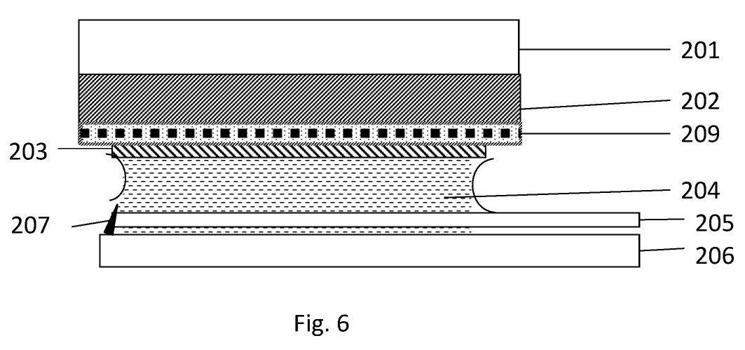

Compared to the embodiment as shown in FIG. 5, in one embodiment as shown in FIG. 6, the rotating driving mechanism drives the chuck 206 to rotate at a high spin speed which is larger than 45 rpm, which causes the gap between the ultra or mega sonic device and the surface of the semiconductor wafer 205 cannot be fully and continuously filled with the cleaning liquid 204, especially at the edge of the ultra or mega sonic device. During the cleaning process, the cleaning liquid 204 fully fills the gap between the ultra or mega sonic device and the surface of the semiconductor wafer 205 off and on, which is unsteady. The gas and liquid phases alternating exists in the gap between the ultra or mega sonic device and the surface of the semiconductor wafer 205. The ultra or mega sonic energy concentrates between the interface of gas and liquid phases. The high ultra or mega sonic power generated by the energy concentration has the risk of the patterned structures damage. Besides, when there is no cleaning liquid 204 filling the gap or the gap is not fully filled with the cleaning liquid 204, where the ultra or mega sonic energy is not transferred to the surface of the semiconductor wafer 205, but once the gap is fully filled with the cleaning liquid 204, the ultra or mega sonic energy is transferred to the surface of the semiconductor wafer 205 through the cleaning liquid 204. It results in a non-uniform distribution of the ultra or mega sonic energy transferred to the surface of the semiconductor wafer 205. Besides, the unstable liquid transferring also causes the turbulence flow, where the ultra or mega sonic energy transferring is further not uniform.

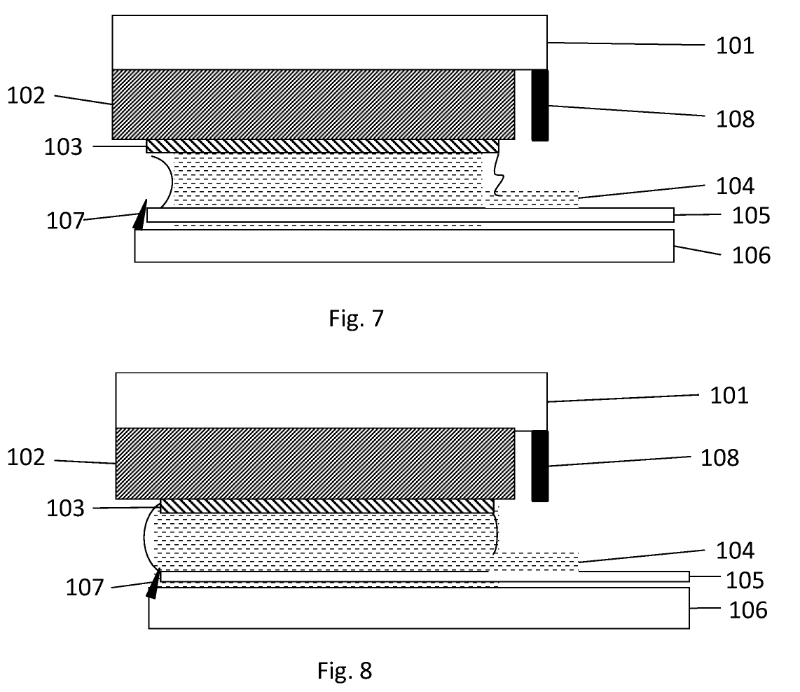

In one embodiment as shown in FIG. 7, when using the apparatus shown in FIG. 1A and FIG. 1B to clean the semiconductor wafer 105, the chuck 106 holds and positions the semiconductor wafer 105 by the plurality of locating pins 107. The rotating driving mechanism 111 drives the chuck 106 to rotate at a low spin speed which is smaller than 30 rpm, preferably in the range of 10-30 rpm. The actuator 113 drives the ultra or mega sonic device to a position above the surface of the semiconductor wafer 105. The vertical actuator 112 drives the suspension arm 101 to move vertically for changing the gap between the ultra or mega sonic device and the surface of the semiconductor wafer 105. The edge of the ultra or mega sonic device is aligned with the outer edge of the semiconductor wafer 105. The center dispenser 108 sprays cleaning liquid 104 on the surface of the semiconductor wafer 105. In this embodiment, the surface of the semiconductor wafer 105 is hydrophobic, which causes the gap between the ultra or mega sonic device and the surface of the semiconductor wafer 105 cannot be fully and continuously filled with the cleaning liquid 104, especially at the edge of the ultra or mega sonic device.

For solving the above problem, the present invention provides another embodiment as shown in FIG. 8. In the embodiment, using the apparatus shown in FIG. 1A and FIG. 1B to clean the semiconductor wafer 105, the chuck 106 holds and positions the semiconductor wafer 105 by the plurality of locating pins 107. The rotating driving mechanism 111 drives the chuck 106 to rotate at a low spin speed which is smaller than 30 rpm, preferably in the range of 10-30 rpm. The actuator 113 drives the ultra or mega sonic device to a position above the surface of the semiconductor wafer 105. The vertical actuator 112 drives the suspension arm 101 to move vertically for changing the gap between the ultra or mega sonic device and the surface of the semiconductor wafer 105. The edge of the ultra or mega sonic device is aligned with the outer edge of the semiconductor wafer 105. The center dispenser 108 sprays cleaning liquid 104 on the surface of the semiconductor wafer 105. The surface of the semiconductor wafer 105 is hydrophilic, which makes the gap between the ultra or mega sonic device and the surface of the semiconductor wafer 105 be fully and continuously filled with the cleaning liquid 104, therefore, the ultra or mega sonic energy is stably transferred to the entire surface of the semiconductor wafer 105 through the cleaning liquid 104, avoiding the ultra or mega sonic energy damaging the patterned structures on the semiconductor wafer 105.

As described above, the spin speed of the chuck, the position of the ultra or mega sonic device, the type of the dispenser and the surface characteristic of the semiconductor wafer are factors which affect the cleaning liquid fills the gap between the ultra or mega sonic device and the surface of the semiconductor wafer. Especially, controlling the chuck spin speed lower than a set spin speed can ensure that the gap between the ultra or mega sonic device and the surface of the semiconductor wafer is fully and continuously filled with the cleaning liquid, making the ultra or mega sonic energy be stably transferred to the entire surface of the semiconductor wafer through the cleaning liquid, avoiding damaging the patterned structures on the semiconductor wafer. For the center dispenser, for avoiding the ultra or mega sonic energy damaging the patterned structures on the semiconductor wafer, the spin speed of the chuck is lower than 30 rpm. For the side dispenser, for avoiding the ultra or mega sonic energy damaging the patterned structures on the semiconductor wafer, the spin speed of the chuck is lower than 45 rpm.

Accordingly, a method for cleaning a semiconductor wafer of the present invention is provided, which includes the following steps:

Step 1: holding a semiconductor wafer by a chuck;

Step 2: spraying cleaning liquid on the surface of the semiconductor wafer;

Step 3: driving an ultra or mage sonic device to a position above the surface of the semiconductor wafer and a gap formed between the ultra or mega sonic device and the surface of the semiconductor wafer; and

Step 4: driving the chuck to rotate at a spin speed lower than a set spin speed for ensuring that the gap between the ultra or mega sonic device and the surface of the semiconductor wafer is fully and continuously filled with the cleaning liquid, making the ultra or mega sonic energy be stably transferred to the entire surface of the semiconductor wafer through the cleaning liquid.

In one embodiment, the surface of the semiconductor wafer is hydrophilic.

In one embodiment, spraying cleaning liquid on the surface of the semiconductor wafer by at least one center dispenser. And driving the chuck to rotate at a spin speed lower than 30 rpm, preferably in the range of 10-30 rpm. The center dispenser is opposite the center of the semiconductor wafer or slightly over the center of the semiconductor wafer.

In one embodiment, spraying cleaning liquid on the surface of the semiconductor wafer by at least one side dispenser. And driving the chuck to rotate at a spin speed lower than 45 rpm, preferably in the range of 10-45 rpm. The side dispenser is disposed at a side of the ultra or mega sonic device. The side dispenser has a plurality of jetting holes which are arranged in a line disposed along the side of the ultra or mega sonic device.

The foregoing description of the present invention has been presented for purposes of illustration and description. It is not intended to be exhaustive or to limit the invention to the precise form disclosed, and obviously many modifications and variations are possible in light of the above teaching. Such modifications and variations that may be apparent to those skilled in the art are intended to be included within the scope of this invention as defined by the accompanying claims.

What is claimed is:

1. An apparatus for cleaning a semiconductor wafer, comprising:
a chuck for holding a semiconductor wafer;
an ultra or mega sonic device;
an actuator for driving the ultra or mage sonic device to a position above the surface of the semiconductor wafer and a gap formed between the ultra or mega sonic device and the surface of the semiconductor wafer;
at least one dispenser for spraying cleaning liquid on the surface of the semiconductor wafer; and
a rotating driving mechanism for driving the chuck to rotate at a spin speed lower than a set spin speed for ensuring that the gap between the ultra or mega sonic device and the surface of the semiconductor wafer is fully and continuously filled with the cleaning liquid, making the ultra or mega sonic energy be stably transferred to the entire surface of the semiconductor wafer through the cleaning liquid.

2. The apparatus according to claim 1, wherein the surface of the semiconductor wafer is hydrophilic.

3. The apparatus according to claim 1, wherein the at least one dispenser is a center dispenser.

4. The apparatus according to claim 3, wherein the rotating driving mechanism drives the chuck to rotate at a spin speed lower than 30 rpm.

5. The apparatus according to claim 4, wherein the rotating driving mechanism drives the chuck to rotate at a spin speed which is in the range of 10-30 rpm.

6. The apparatus according to claim 3, further comprising a suspension arm, the ultra or mega sonic device is positioned at the bottom of the suspension arm, the center dispenser is positioned at the tip end of the suspension arm.

7. The apparatus according to claim 3, wherein the center dispenser is opposite the center of the semiconductor wafer or slightly over the center of the semiconductor wafer.

8. The apparatus according to claim 1, wherein the at least one dispenser is a side dispenser disposed at a side of the ultra or mega sonic device.

9. The apparatus according to claim 8, wherein the rotating driving mechanism drives the chuck to rotate at a spin speed lower than 45 rpm.

10. The apparatus according to claim 9, wherein the rotating driving mechanism drives the chuck to rotate at a spin speed which is in the range of 10-45 rpm.

11. The apparatus according to claim 8, wherein the side dispenser has a plurality of jetting holes which are arranged in a line disposed along the side of the ultra or mega sonic device.

12. The apparatus according to claim 1, further comprising a vertical actuator for driving the ultra or mega sonic device to move vertically for changing the gap between the ultra or mega sonic device and the surface of the semiconductor wafer.

13. The apparatus according to claim 1, further comprising a plurality of locating pins disposed on the chuck for fixing the semiconductor wafer.

14. A method for cleaning a semiconductor wafer, comprising:
holding a semiconductor wafer by a chuck;
spraying cleaning liquid on the surface of the semiconductor wafer;
driving an ultra or mage sonic device to a position above the surface of the semiconductor wafer and a gap formed between the ultra or mega sonic device and the surface of the semiconductor wafer; and
driving the chuck to rotate at a spin speed lower than a set spin speed for ensuring that the gap between the ultra or mega sonic device and the surface of the semiconductor wafer is fully and continuously filled with the cleaning liquid, making the ultra or mega sonic energy be stably transferred to the entire surface of the semiconductor wafer through the cleaning liquid.

15. The method according to claim 14, wherein the surface of the semiconductor wafer is hydrophilic.

16. The method according to claim 14, wherein spraying cleaning liquid on the surface of the semiconductor wafer by at least one center dispenser.

17. The method according to claim 16, wherein driving the chuck to rotate at a spin speed lower than 30 rpm.

18. The method according to claim 17, wherein driving the chuck to rotate at a spin speed which is in the range of 10-30 rpm.

19. The method according to claim 16, wherein the center dispenser is opposite the center of the semiconductor wafer or slightly over the center of the semiconductor wafer.

20. The method according to claim 14, wherein spraying cleaning liquid on the surface of the semiconductor wafer by at least one side dispenser.

21. The method according to claim 20, wherein driving the chuck to rotate at a spin speed lower than 45 rpm.

22. The method according to claim 21, wherein driving the chuck to rotate at a spin speed which is in the range of 10-45 rpm.

23. The method according to claim 20, wherein the side dispenser is disposed at a side of the ultra or mega sonic device.

24. The method according to claim 23, wherein the side dispenser has a plurality of jetting holes which are arranged in a line disposed along the side of the ultra or mega sonic device.
